(19) United States
(12) Patent Application Publication
(10) Pub. No.: US 2025/0140564 A1
(43) Pub. Date: May 1, 2025

(54) METHOD OF ETCHING SILICON-CONTAINING FILM AND METHOD OF MANUFACTURING SEMICONDUCTOR DEVICE INCLUDING THE SAME

(71) Applicant: SK Specialty Co., Ltd., Yeongju-si (KR)

(72) Inventors: Byunghyang KWON, Sejong-si (KR); Junghun KWAK, Sejong-si (KR); Yongjun CHO, Sejong-si (KR); Jinhee LEE, Sejong-si (KR); Gi-Chung KWON, Seoul (KR); Woo Jae KIM, Seoul (KR); In Young BANG, Seoul (KR); Hyeon Jo KIM, Seoul (KR)

(21) Appl. No.: 18/926,678

(22) Filed: Oct. 25, 2024

(30) Foreign Application Priority Data
Oct. 27, 2023 (KR) 10-2023-0145692

(51) Int. Cl. H01L 21/311; H01L 21/3213

(52) U.S. Cl. CPC H01L 21/31116; H01L 21/32137

(57) ABSTRACT

The present disclosure relates to a method of etching a silicon-containing film, and more specifically, to a method of etching a silicon-containing film using an etching gas containing nitrosyl fluoride (FNO) and a method of manufacturing a semiconductor device including the same.

### CROSS REFERENCE TO RELATED APPLICATION

The present application claims priority to Korean Patent Application No. 10-2023-0145692, filed on Oct. 27, 2023, the entire contents of which is incorporated herein for all purposes by this reference.

### BACKGROUND OF THE INVENTION

### Field of the Invention

The present disclosure relates to a method of etching a silicon-containing film, and more specifically, to a method of etching a silicon-containing film using an etching gas containing nitrosyl fluoride (FNO) and a method of manufacturing a semiconductor device including the same.

### Description of the Related Art

In general, a series of processes such as deposition, etching, ion implantation, and cleaning are performed to manufacture a semiconductor device. These processes are performed in a process chamber capable of maintaining process conditions in a state with various process conditions such as an atmospheric pressure, low pressure, and vacuum. Among the processes, the etching process is a process of selectively removing a portion of a thin film formed on a substrate by a deposition process, etc. to form an ultrafine structure (pattern, etc.) in a desired shape.

The etching process, especially, a dry etching process, injects an etching gas in a gaseous state, reacts with the injected etching gas and an etching target (e.g., a silicon-containing film) on the substrate to form a volatile byproduct, thereby removing a portion or the entirety of the thin film. As a method of the dry etching process, a plasma etching method using active ions or generally using plasma to increase reactivity between an etching gas and an etching target is mainly used. The plasma etching method is a method of converting an etching gas into plasma to form highly reactive radicals and ions and allowing these radicals and ions to physically or chemically etch the etching target.

As the method of the dry etching process, there is a plasma etching method, such as a capacitively coupled plasma (CCP) method, an inductively coupled plasma (ICP) method, a remote plasma system (RPS) method, a plasma method by electron cyclotron resonance (ECR), a transformer coupled plasma (TCP) method, a high density plasma (HDP) method, reactive ion etching (RIE), or magnetically enhanced reactive ion etching, magnetically enhanced RIE.

A direct plasma technology is mainly used for converting an etching gas into plasma. The direct plasma technology is a method of coming plasma generated by directly applying power to a process chamber, such as CCP or ICP into direct contact with a substrate and an etching target. In this case, inert gases such as helium (He), nitrogen (N₂), and argon (Ar) are injected by being mixed to help the conversion of the etching gas into plasma and accelerate physical etching.

In the etching process, to form an ultrafine structure in a desired shape, while the etching target to be etched should have a high etch rate, a thin film that does not need to be etched should have a low etch rate. A ratio of an etch rate of the thin film to be etched and an etch rate of the thin film that does not need to be etched is referred to as a selectivity, and a reaction gas with a high selectivity is required for the etching process. In particular, to manufacture semiconductor devices that may be miniaturized or highly integrated, it is necessary to develop a reaction gas with a higher selectivity.

Conventionally, a large amount of perfluoro compound gases such as CF₄, C₃F₆, SF₆, and NF₃ have been used as a reaction gas. However, since the conventional perfluoro compound reaction gases have difficulties in treating waste gases discharged after the etching process, much treatment costs are required before the waste gases are discharged into the atmosphere. In addition, the conventional perfluoro compound gases have a long atmospheric lifetime and a very high global warming potential (GWP), which is pointed out as major factors in a change in climate.

Therefore, an alternative reaction gas that has a low GWP and excellent etching performance, especially, selectivity, for silicon-containing films is required.

### SUMMARY OF THE INVENTION

The present disclosure intends to solve the problems of the related art and is directed to providing a method of etching a silicon-containing film, which replaces a reaction gas containing a conventional perfluoro compound gas to use an eco-friendly etching gas having a low global warming potential as a dry etching method.

In addition, the present disclosure is directed to providing a method of etching a silicon-containing film with a high selectivity by activating an etching gas containing an inert gas (argon, etc.) that assists the generation of plasma and performs physical etching into plasma.

In addition, the present disclosure is directed to providing a method of manufacturing a semiconductor device including the method of etching the silicon-containing film.

The objects of the present disclosure are not limited to the above-described object, and other objects and advantages of the present disclosure which are not mentioned can be understood by the following description and more clearly understood by embodiments of the present disclosure. In addition, it can be easily seen that the objects and advantages of the present disclosure can be achieved by means and combinations thereof which are described in the claims.

To achieve the above objects, according to an aspect of the present disclosure, there may be provided a method of etching a silicon-containing film, which includes introducing a substrate including a first silicon-containing film and a second silicon-containing film into a process chamber of an etching device, supplying an etching gas including a reaction gas and an inert gas to the process chamber, generating a radical and ion of the etching gas in the process chamber maintained at a predetermined pressure, and etching the first silicon-containing film on the substrate by the radical of the etching gas, wherein the reaction gas includes a nitrosyl fluoride (FNO) gas, and the predetermined pressure is set so that a sign of a slope with respect to an etch rate of the first silicon-containing film differs from a sign of a slope with respect to an etch rate of the second silicon-containing film.

The first silicon-containing film and the second silicon-containing film may be different and may be each independently selected as any one of a silicon oxide film, a silicon nitride film, a polysilicon film, and a silicide film.

The first silicon-containing film may include a silicon nitride film, and the second silicon-containing film may include a silicon oxide film.

Based on a total content of the reaction gas and the inert gas of 100 vol %, the reaction gas may be included in an amount of 20 vol % or more.

The inert gas may include one or more of argon (Ar), nitrogen (N₂), and helium (He).

The predetermined pressure may be adjusted within a range of 100 mTorr to 1 Torr and according to one embodiment, adjusted within a range of 350 mTorr to 500 mTorr.

The generating of the radical of the etching gas may include a plasma etching method.

The plasma etching method may be one of a capacitively coupled plasma (CCP) method, an inductively coupled plasma (ICP) method, a remote plasma system (RPS) method, a plasma method by electron cyclotron resonance (ECR), a transformer coupled plasma (TCP) method, a high density plasma (HDP) method, reactive ion etching (RIE), or magnetically enhanced reactive ion etching, magnetically enhanced RIE.

According to another aspect of the present disclosure, there may be provided a method of manufacturing a semiconductor device including the method of etching the silicon-containing film according to one aspect of the present disclosure.

### BRIEF DESCRIPTION OF THE DRAWINGS

FIG. 1 is a schematic diagram of an etching device including a process chamber for performing an etching method according to one embodiment of the present disclosure.

FIG. 2 is a flowchart of an etching method of a silicon-containing film according to one embodiment of the present disclosure.

FIG. 3 is a graph showing an etching rate according to an etching gas ratio, pressure, and applied power of a silicon nitride film.

FIG. 4 is a graph showing an etching rate according to the etching gas ratio, pressure, and applied power of the silicon nitride film.

FIG. 5 is a graph showing selectivity of silicon nitride and silicon oxide according to an etching gas ratio, pressure, and applied power.

### DETAILED DESCRIPTION OF THE INVENTION

The above-described objects, features, and advantages will be described below in detail with reference to the accompanying drawings, and thus those skilled in the art to which the present disclosure pertains will be able to easily carry out the technical spirit of the present disclosure. In describing the present disclosure, when it is determined that a detailed description of the known technology related to the present disclosure may unnecessarily obscure the gist of the present disclosure, a detailed description thereof will be omitted.

In describing the present specification, when it is determined that the detailed description of a related known technology may unnecessarily obscure the gist of the present specification, detailed description thereof will be omitted.

In the present specification, when “including,” “containing,” “having,” “consisting of,” “arranging,” “providing,” and the like are used, other portions can be added unless “only” is used. When a component is expressed in the singular, it includes a case in which the component is provided as a plurality of components unless specifically stated otherwise.

In construing a component in the present specification, the component is construed as including the margin of error even when there is no separate explicit description.

Hereinafter, the present disclosure will be described in more detail.

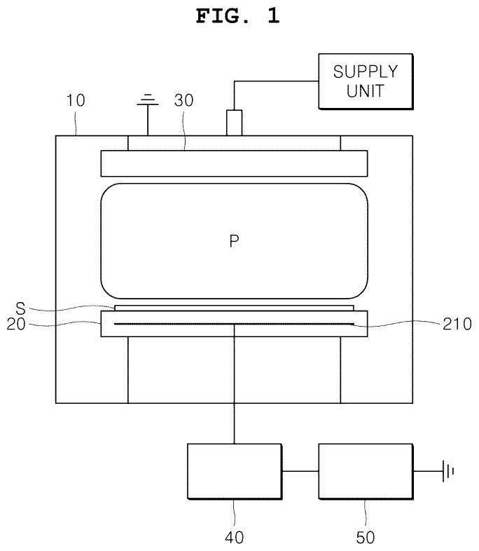

FIG. 1 is a schematic diagram of an etching device using capacitively coupled plasma (CCP) as an example of an etching device including a process chamber for performing an etching method according to one embodiment of the present disclosure. The etching device is configured to generate plasma P by applying predetermined power while maintaining a predetermined pressure condition and includes a process chamber 10, a substrate holder 20, a shower head 30, an impedance matching network 40, an RF power source 50, a gas supply unit, etc. The substrate S includes a silicon semiconductor substrate including a silicon-containing film. An etching device 1 may be configured to easily generate the plasma P near a surface of the substrate S or configured to easily cause a chemical reaction. The process chamber 10 may be configured to maintain a predetermined pressure condition during the process and may further include a substrate insertion device (not shown) for inserting the substrate before and after the process. In addition, a vacuum system (not shown) including a vacuum pump may be connected so that the process chamber 10 may reach and maintain a specific pressure condition.

The substrate holder 20 is configured to hold the substrate S and generate direct plasma to perform the process. In this case, the substrate holder 20 includes a discharge electrode 210 for applying power to an etching gas in the process chamber to generate direct plasma. In addition, although not shown in FIG. 1, the substrate holder 20 may include a heater and a coolant flow path for controlling a temperature of the substrate S during the process. In addition, although not shown in FIG. 1, the substrate holder 20 may include a substrate fixing means such as an electrostatic chuck to fix the substrate S during the process.

An etching gas including a reaction gas and an inert gas may be supplied to the shower head 30 at a constant flow rate through the gas supply unit and injected into the process chamber 10. In this case, the gas supply unit may include a gas supply system including a mass flow controller (MFC) to maintain a constant flow rate of the etching gas. Although not shown in FIG. 1, an RF power source and an impedance matching system for generating direct plasma may be additionally connected to the shower head 30.

The RF power source 50 and the impedance matching network 40 that are connected to the discharge electrode 210 are configured to generate direct plasma in the process chamber of the etching device. The RF power source and the impedance matching network transmit predetermined power to the discharge electrode to generate direct plasma. Two or more RF power sources and impedance matching networks may be added to apply different powers and frequencies.

In FIG. 1, when the etching gas supplied from the gas supply unit is supplied through the shower head 30, the pressure in the process chamber reaches a predetermined pressure condition through a vacuum system (not shown), etc. In this case, the substrate holder 20 fixes the substrate through the substrate fixing means (not shown). When the predetermined pressure condition required for the process is reached, predetermined power is applied from the RF power source 50. In this case, the impedance matching network 40 matches impedances of the RF power source and the etching device to transmit the maximum power to the substrate electrode 210. A strong AC electric field is generated between the shower head 30 and the substrate holder 20 by the applied RF power source to generate the plasma P. In the generated plasma P, radicals, ions, etc. are generated, and the components generated in this way chemically react with the substrate or physically etch the substrate to etch the silicon-containing film formed on the substrate S.

The etching device of FIG. 1 has a structure in which the RF power source is connected to the substrate holder 20, but the etching device is not limited thereto, and a form in which the RF power source is connected to the shower head 30 to reduce physical etching is also possible. In addition, the etching device of the present disclosure may have a coil antenna disposed to use inductively coupled plasma (ICP), and the RF power source may be connected to the coil antenna. In addition, the etching device of the present disclosure may have a form in which a separate remote plasma device for supplying only radicals and ions is coupled to the process chamber.

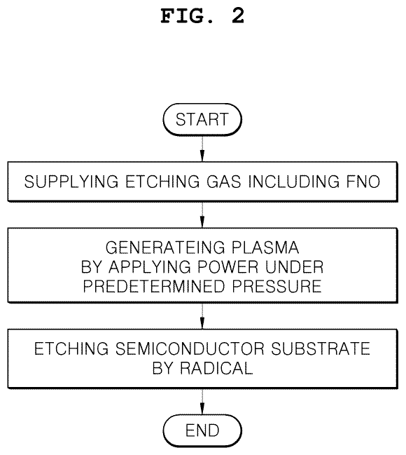

FIG. 2 is a flowchart of the etching method according to an embodiment of the present disclosure. Referring to FIG. 2, first, an etching gas is supplied for etching the substrate S including the silicon-containing film fixed to the substrate holder 20 in the process chamber 10 of the etching device.

In this case, the silicon-containing film formed on the substrate S may include a silicon oxide film, a silicon nitride film, a polysilicon (p-Si) film, a silicide film, etc. and include at least two types of silicon-containing films, such as a first silicon-containing film and a second silicon-containing film, and the first silicon-containing film and the second silicon-containing film are different. According to one embodiment of the present invention, a silicon nitride film may be selected as the first silicon-containing film, and a silicon oxide film may be selected as the second silicon-containing film. In addition, the etching method of the present disclosure may be applied to etch other types of silicon-containing films other than the listed silicon-containing films.

The supplied etching gas includes a reaction gas including nitrosyl fluoride (FNO) and an inert gas including argon, helium, etc., and the reaction gas and the inert gas are mixed at an appropriate ratio and supplied at a constant flow rate.

In this case, according to an etching target or an etching process, another control gas (H₂, H₂O, HBr, etc.) may be further included. A ratio of the reaction gas and the inert gas may be adjusted depending on the added control gas.

When the etching gas is supplied to the process chamber 10, a device such as a vacuum system (not shown) may be used to maintain the pressure in the process chamber at an appropriate pressure condition. In addition, the temperature of the substrate S may be maintained at an appropriate temperature condition through the heater (not shown) and the coolant flow path (not shown) in the substrate holder as needed.

Then, by applying appropriate power to the etching device through the RF power source 50 under appropriate pressure and temperature conditions, the plasma P is generated in the process chamber 10. The radicals and ions generated in the plasma P react with the silicon-containing film on the substrate S to form volatile byproducts, thereby etching the etching target. The plasma is maintained for an appropriate time so that a desired ultrafine structure may be formed on the substrate during the etching operation.

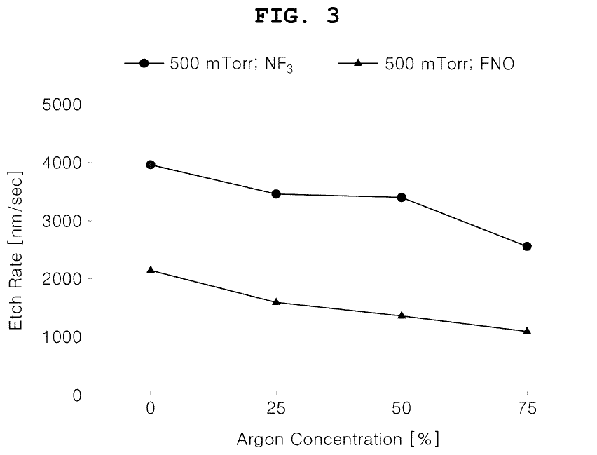

Hereinafter, the etch rate and etching selectivity of the silicon-containing film according to the pressure condition of 500 mTorr when generating the direct plasma of the etching gas including FNO will be described with reference to FIGS. 3 to 5, and in FIGS. 3 to 5, a case of using NF₃ as the conventional reaction gas is referred to as a “Comparative Example,” and a case of using FNO according to the present disclosure is referred to as an “Example.”

FIG. 3 is a graph showing an etch rate of a silicon nitride (SiN) film according to the ratio of the reaction gas and the inert gas under the pressure condition of 500 mTorr when generating direct plasma while flowing the etching gas into the etching device at a total flow rate of 200 sccm in a direct plasma generating operation.

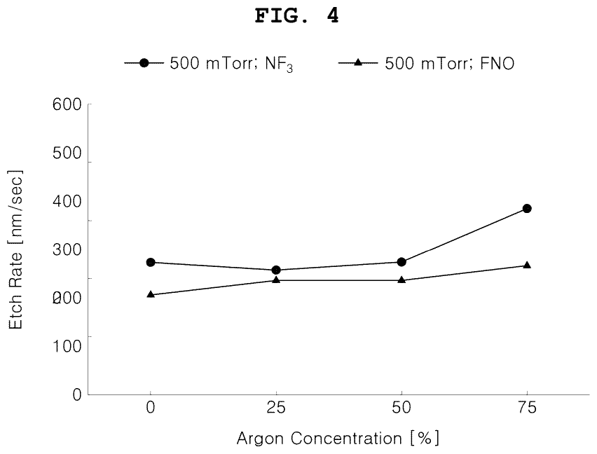

FIG. 4 is a graph showing an etch rate of a silicon oxide (SiO₂) film according to the ratio of the reaction gas and the inert gas under the pressure condition of 500 mTorr when generating direct plasma under the same condition as the case of FIG. 3 in a plasma generating operation.

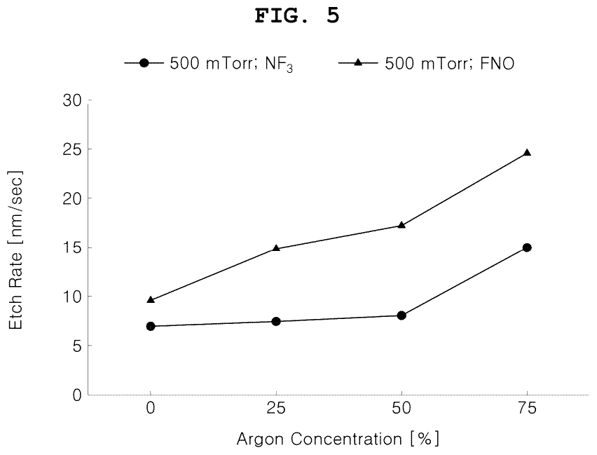

FIG. 5 shows an etching selectivity of a silicon nitride film to a silicon oxide film under the ratio of the reaction gas and the inert gas and the pressure condition of 500 mTorr in the plasma generating operation.

As shown in FIG. 3, in the etching of the silicon nitride film by the direct plasma of the etching gas containing FNO, the etch rate of the silicon nitride film decreases proportionally as the ratio of the reaction gas containing FNO and the inert gas containing argon increases. That is, the slope of the etch rate with respect to the ratio in FIG. 3 is negative.

Meanwhile, as shown in FIG. 4, in the etching of the silicon oxide film by the direct plasma of the etching gas containing FNO, the etch rate of the silicon oxide film increases proportionally as the ratio of argon increases with respect to the ratio of the reaction gas containing FNO and the inert gas containing argon, and thus the slope of the etch rate with respect to the ratio of the argon gas in FIG. 4 is positive.

In manufacturing a semiconductor device, there is a case in which an etching selectivity of a silicon nitride film with respect to a silicon oxide film needs to be as great as possible. To this end, it is necessary to maintain conditions of making the etch rate of the silicon nitride film as high as possible while making the etch rate of the silicon oxide film as low as possible under the same conditions. As shown in FIGS. 3 and 4, in the etching of the silicon nitride and silicon oxide films by the direct plasma using the etching gas that is mixed with the reaction gas containing FNO and the inert gas containing argon gas, etch rate behaviors of the silicon nitride and silicon oxide films according to the ratio of the reaction gas and inert gas and the pressure are different. Therefore, using this, the etching selectivity of the silicon nitride film to the silicon oxide film can be significantly improved by appropriately adjusting the ratio of the reaction gas and the inert gas and the pressure when generating the direct plasma of the etching gas containing FNO.

As shown in FIG. 5, it can be seen that the etching selectivity of the silicon nitride film to the silicon oxide film is improved when using FNO according to the present disclosure (Example) compared to a case of using NF₃ as a reaction gas as in the related art (Comparative Example). In addition, as the ratio of the inert gas to the total etching gas increases, the etching selectivity of the silicon nitride film to the silicon oxide film can be greatly increased.

In the present disclosure, the pressure condition may be adjusted, for example, within a range of 100 to 1,000 mTorr, for example, within a range of 100 to 800 mTorr, for example, within a range of 200 to 700 mTorr, for example, within a range of 300 to 600 mTorr, for example, within a range of 350 to 500 mTorr. As the ratio of the inert gas to the etching gas increases within the above pressure range, while the etch rate of the silicon nitride film decreases, the etch rate of the silicon oxide film increases, thereby improving a selectivity.

As shown in FIGS. 3 to 5, while the selectivity increases when the ratio of the inert gas increases, the ratio of the reaction gas decreases when the ratio of the inert gas becomes too high, thereby lowering etching performance. From this point of view, based on the total content of the reaction gas and the inert gas of 100 vol %, the reaction gas is included in an amount of, for example, 20 vol % or more, preferably, 25vol % or more. In addition, based on the total content of the reaction gas and the inert gas of 100 vol %, the ratio of the inert gas may be within the range of 0 to 80 vol % and may be within the range of 25 to 75 vol %.

However, the present disclosure is not limited thereto, and even when the signs of the slopes of the graphs of the etch rates are the same, when absolute values of the slopes of the etch rates according to the pressures of the silicon nitride film and the silicon oxide film are different, the etching selectivity of the silicon nitride film with respect to the silicon oxide film may be increased by adjusting the pressure conditions.

That is, as the ratio of the inert gas to the etching gas increases in a predetermined pressure range or as the pressure increases, rates of changes in etch rates of the silicon nitride film and the silicon oxide film find different pressure ranges to select pressure conditions so that the etching selectivity is maximized.

According to the present disclosure, an etching gas containing FNO can be eco-friendly due to a low GWP and can perform etching the silicon-containing film with a high selectivity.

The effects of the present disclosure together with the above-described effects are described together with a description of the following matters for carrying out the disclosure.

Although the present disclosure has been described above in more detail with reference to the embodiments and drawings of the present specification, the present specification is not necessarily limited to these embodiments and drawings, and various modifications can be made without departing from the technical spirit of the present specification. Therefore, the embodiments and drawings disclosed in the present specification are not intended to limit the technical spirit of the present specification, but are intended to describe the same, and the scope of the technical spirit of the present specification is not limited by these embodiments. Therefore, it should be understood that the above-described embodiments are illustrative and not restrictive in all aspects.

What is claimed is:

1. A method of etching a silicon-containing film, comprising:
introducing a substrate including a first silicon-containing film and a second silicon-containing film into a process chamber of an etching device;
supplying an etching gas including a reaction gas and an inert gas to the process chamber;
generating a radical of the etching gas in the process chamber maintained at a predetermined pressure; and
etching the first silicon-containing film on the substrate by the radical of the etching gas,
wherein the reaction gas includes a nitrosyl fluoride (FNO) gas, and
the predetermined pressure is set so that a sign of a slope with respect to an etch rate of the first silicon-containing film differs from a sign of a slope with respect to an etch rate of the second silicon-containing film.

2. The method of claim 1, wherein the first silicon-containing film and the second silicon-containing film are different and are each independently selected as any one of a silicon oxide film, a silicon nitride film, a polysilicon film, and a silicide film.

3. The method of claim 1, wherein the first silicon-containing film includes a silicon nitride film, and
the second silicon-containing film includes a silicon oxide film.

4. The method of claim 1, wherein based on a total content of the reaction gas and the inert gas of 100 vol %, the reaction gas is included in an amount of 20 vol % or more.

5. The method of claim 1, wherein the inert gas includes one or more of argon (Ar), nitrogen (N₂), and helium (He).

6. The method of claim 1, wherein the predetermined pressure is adjusted within a range of 100 mTorr to 1 Torr.

7. The method of claim 1, wherein the predetermined pressure is adjusted within a range of 350 mTorr to 500 mTorr.

8. The method of claim 1, wherein the generating of the radical of the etching gas includes a plasma etching method.

9. The method of claim 8, wherein the plasma etching method is one of a capacitively coupled plasma (CCP) method, an inductively coupled plasma (ICP) method, a remote plasma system (RPS) method, a plasma method by electron cyclotron resonance (ECR), a transformer coupled plasma (TCP) method, a high density plasma (HDP) method, reactive ion etching (RIE), or magnetically enhanced reactive ion etching, magnetically enhanced RIE.

10. A method of manufacturing a semiconductor device including the method of claim 1.
